(19) United States
(12) Patent Application Publication
(10) Pub. No.: US 2018/0240887 A1
(43) Pub. Date: Aug. 23, 2018

(54) Semiconductor Device and Method of Manufacturing the Same

(71) Applicant: Infineon Technologies AG, Neubiberg (DE)

(72) Inventors: Matthias Koenig, Freising (DE); Marco Kraus, Regensburg (DE); Guenther Ruhl, Regensburg (DE)

(21) Appl. No.: 15/895,427

(22) Filed: Feb. 13, 2018

(30) Foreign Application Priority Data
Feb. 22, 2017 (DE) 102017103666.0

(51) Int. Cl. H01L 29/66; H01L 27/12; H01L 29/16; H01L 29/10

(52) U.S. Cl. CPC H01L 29/66045; H01L 27/1203; H01L 29/1083; H01L 29/1606; H01L 29/66977

(57) ABSTRACT

A method for use in manufacturing an electronic component comprises forming a layered structure comprising a dielectric structure layer, a channel layer and a gate layer. The dielectric structure layer comprises a first portion and a second portion that differ from one another in respect of fixed charges. The channel layer comprises a two-dimensional material. The gate layer comprises a gate formed above both, the first portion of the dielectric structure layer and the second portion of the dielectric structure layer. A device for use as an electronic component comprises a dielectric structure and a gate above the dielectric structure and a two-dimensional material between the dielectric structure and the gate. The dielectric structure is configured to expose the two-dimensional material to an inhomogeneous electric field.

This application claims the benefit of German Application No. 102017103666.0, filed on Feb. 22, 2017, which application is hereby incorporated herein by reference in its entirety.

### TECHNICAL FIELD

Various embodiments relate generally to two-dimensional material containing electronic components.

### BACKGROUND

A graphene field effect transistor (GFET) device is a derivate of a normal FET with source, drain and gate contact, but instead of doped silicon, graphene is used for the electrical channel.

Graphene is a semiconductor material having a large charge carrier mobility. Graphene as a transistor channel offers the option to go to frequencies in the THz range. However, monolayer graphene has no band gap so that a transistor based on graphene cannot be completely switched off. Due to its missing band gap, a graphene field effect transistor does not switch off completely (on-off ratio 2-10).

One possibility to generate a band gap is to provide a two-layer graphene, to which an electric field may be applied perpendicular to the graphene layer direction. In a conventional embodiment of a transistor based on graphene as described above, the electric field is generated by a further electrode (bottom gate) provided next to the actual gate electrode (top gate) of the transistor. This design requires a correspondingly complex expense for this further electrode. At the same time, the leakage current between the transistor channel and this further electrode results in a corresponding power loss.

Another possibility to generate a band gap is chemical doping. Adsorption of chemical dopants represents one way to dope graphene. Materials like polyethylene imine (n-type) or diazonium salts (p-type) are deposited via several processes onto the graphene layer (atomic layer deposition, liquid chemical treatments etc.).

### SUMMARY

The following presents a simplified summary in order to provide a basic understanding of one or more aspects of the invention. This summary is not an extensive overview of the invention, and is neither intended to identify key or critical elements of the invention, nor to delineate the scope thereof. Rather, the primary purpose of the summary is to present some concepts of the invention in a simplified form as a prelude to the more detailed description that is presented later.

In an aspect, a device for use as an electronic component comprises a dielectric structure. In some embodiments, the device comprises a gate above the dielectric structure and a two-dimensional material between the dielectric structure and the gate. The dielectric structure is configured to expose the two-dimensional material to an inhomogeneous electric field. In some embodiments, the device comprises a gate layer and a two-dimensional material between the dielectric structure and the gate layer. The dielectric structure is configured to expose the two-dimensional material to an inhomogeneous electric field. The gate layer comprises a plurality of gates each configured to control current in the channel layer.

This summary is submitted with the understanding that it will not be used to interpret or limit the scope or meaning of the claims. This summary is not intended to identify key features or essential features of the claimed subject matter, nor is it intended to be used as an aid in determining the scope of the claimed subject matter. Other methods, apparatus and systems are also disclosed. Those skilled in the art will recognize additional features and advantages upon reading the following detailed description, and upon viewing the accompanying drawings.

### BRIEF DESCRIPTION OF THE DRAWINGS

The claimed subject matter is described below with reference to the drawings. As used herein, like terms refer to like elements throughout the description. The detailed description references the accompanying figures. The same numbers can be used throughout the drawings to reference like features and components. Further, in different drawings like features or corresponding features can be indicated by reference numerals that have the last two digits in common. It should be noted that views of exemplary embodiments are merely to illustrate selected features of the embodiment. In particular, cross-sectional views are not drawn to scale and dimensional relationships of the illustrated structures can differ from those of the illustrations.

FIG. 1 shows a flow chart that illustrates steps of an exemplary method according to some implementations;

FIGS. 2A to 2F show a schematic cross-sectional view of a workpiece that illustrates an exemplary portion of a wafer according to some embodiments;

FIG. 3A shows a schematic cross-sectional view of an exemplary electronic component according to some embodiments;

FIGS. 3B and 3C show band diagrams that illustrate properties of the electronic component in some implementations;

FIG. 4 is a schematic cross-sectional view that illustrates an electronic component according to some embodiments;

FIG. 5 shows a diagram that illustrates exemplary characteristic behavior of the electronic component according to some embodiments;

FIG. 6 is a schematic cross-sectional view that illustrates an electronic component according to some embodiments; and

FIG. 7 shows a diagram that illustrates exemplary characteristic behavior of the electronic component according to some embodiments.

### DETAILED DESCRIPTION OF ILLUSTRATIVE EMBODIMENTS

For purposes of explanation, numerous specific details are set forth in order to provide a thorough understanding of the claimed subject matter. It may be evident, however, that the claimed subject matter may be practiced without these specific details.

The following detailed description refers to the accompanying drawings that show, by way of illustration, specific details and embodiments in which the invention may be practiced. These embodiments are described in sufficient detail to enable those skilled in the art to practice the invention. Other embodiments may be utilized and structural, logical, and electrical changes may be made without departing from the scope of the invention. The various embodiments are not necessarily mutually exclusive, as some embodiments can be combined with one or more other embodiments to form new embodiments. Various embodiments are described in connection with methods and various embodiments are described in connection with devices. However, it may be understood that embodiments described in connection with methods may similarly apply to the devices, and vice versa.

Described herein are techniques that can be useful, for example, in the field of electronic components. Embodiments disclosed herein encompass a method for use in manufacturing an electronic component, and an electronic component. In an aspect, a method for use in manufacturing an electronic component comprises forming a layered structure comprising a dielectric structure layer, a channel layer and a gate layer. The dielectric structure layer comprises a first portion and a second portion. The first and second portions differ from one another in respect of fixed charges. It should be understood that fixed charges can be in a material's lattice, for example, due to defects in the material's lattice. Fixed charges can also be in the material due to “dopant” atoms that are built into the material and that have a nuclear charge that differs from the nuclear charge of a majority of atoms that make up the material. The channel layer of the electronic component comprises a two-dimensional material. In some embodiments, the gate layer comprises a gate formed above both, the first portion of the dielectric structure layer and the second portion of the dielectric structure layer. In some embodiments, the gate layer comprises a first gate above the first portion of the dielectric structure layer and a second gate above the second portion of the dielectric structure layer.

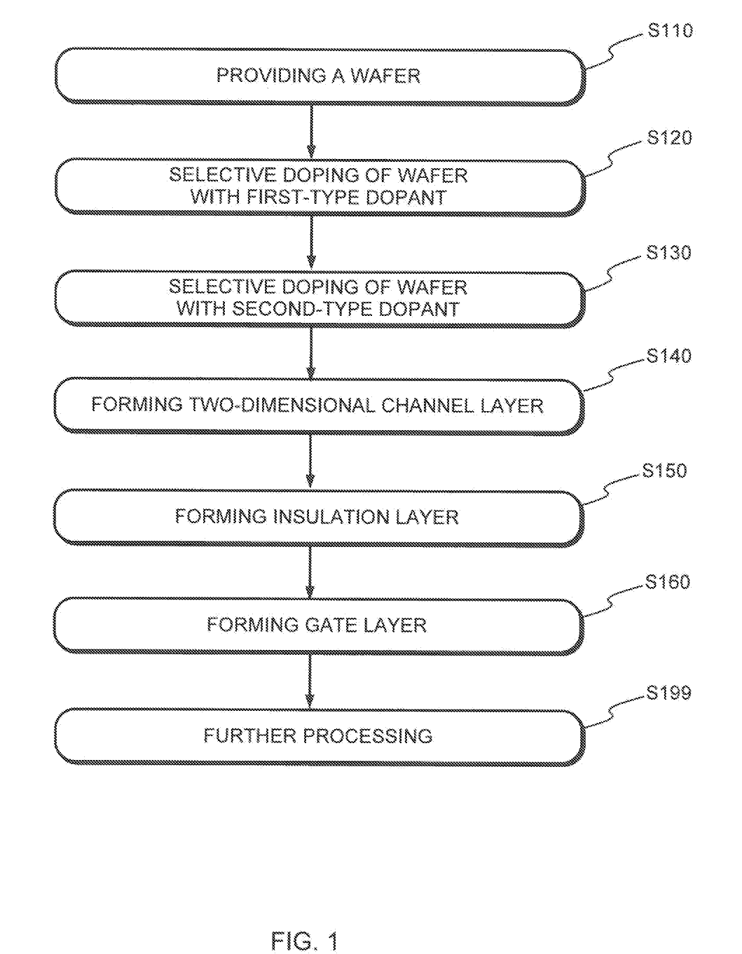

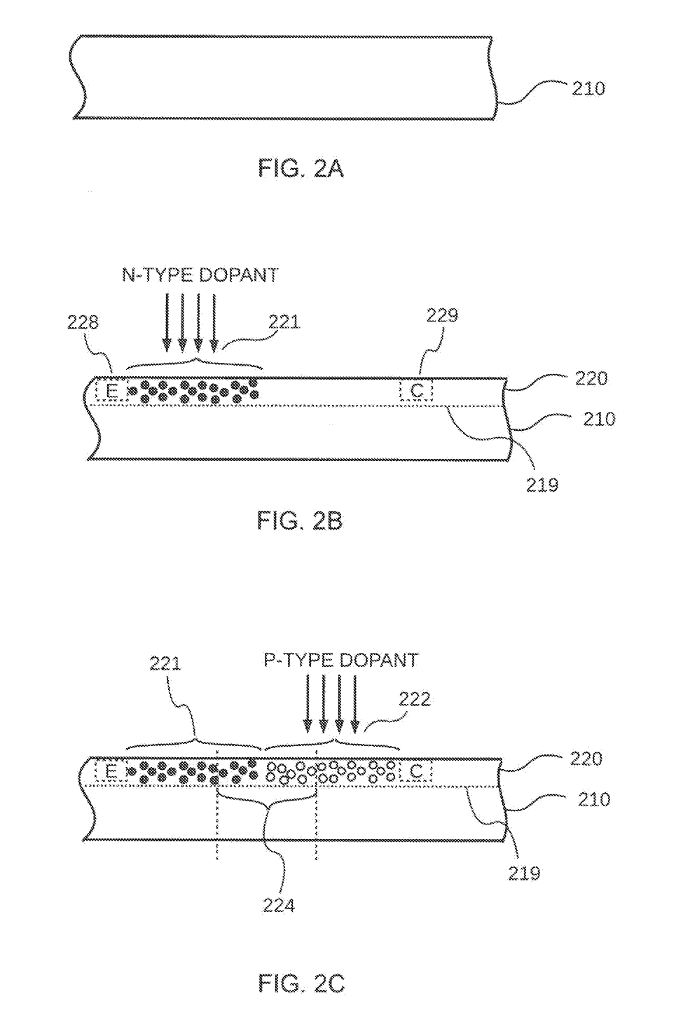

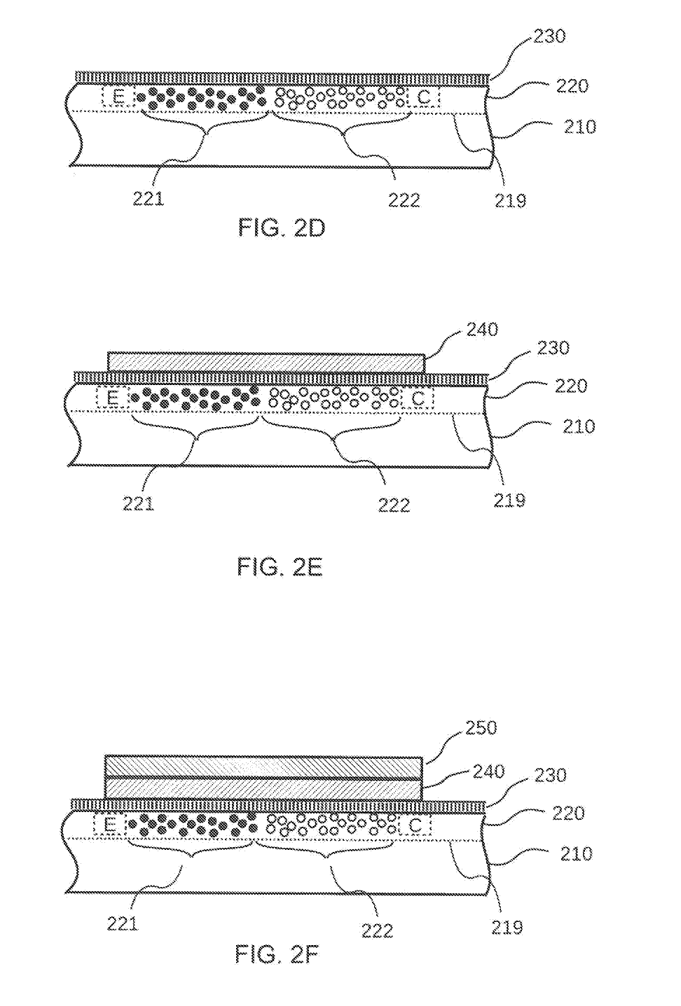

Below, an exemplary implementation of a method for use in manufacturing an electronic component will be described with reference to FIG. 1 that shows a flow chart that illustrates steps of an exemplary method according to some implementations. Further, reference will be made to FIGS. 2A to 2F that show a schematic cross-sectional view of a workpiece that illustrates an exemplary portion of a wafer according to some embodiments.

In an aspect, the invention encompasses a method for use in manufacturing an electronic component. The method comprises forming a layered structure comprising a dielectric structure layer, a channel layer and a gate layer.

At S110, an exemplary implementation of a method for use in manufacturing an electronic component such as a diode or a field effect transistor (FET) comprises providing a base substrate, herein also briefly referred to as carrier. For example, the substrate may be made of semiconductor materials of various types. For example, the semiconductor material can be a group IV semiconductor such as silicon, silicon carbide, germanium, and silicon germanium. In some embodiments, the substrate material is based on a group IV element. The semiconductor material can include silicon, germanium, group III to V materials or other types of material, including polymers. In various embodiments, the substrate is made of silicon. For example, as indicated in FIG. 2A, a semiconductor wafer 210 such as a silicon wafer is provided as a workpiece in order to perform further manufacturing steps on the wafer, for example, at least some of the steps described below. As an alternative, any other suitable semiconductor materials can be used for the substrate, for example semiconductor compound material such as silicon carbide (SiC), gallium nitride (GaN), gallium arsenide (GaAs), indium phosphide (InP), but also any suitable ternary semiconductor compound material such as indium gallium arsenide (InGaAs) or quaternary semiconductor compound material. Furthermore, in various embodiments, the substrate may include dielectric material such as e.g. silicon oxide (SiO2), silicon nitride (Si3N4), silicon carbide (SiC), aluminum oxide (Al2O3), hafnium oxide or zirconium oxide (ZrO2).

In an alternative embodiment, the substrate is a silicon-on-insulator (SOI) wafer. The substrate may, for example, be an insulator such as a ceramic material, glass, carbon or plastic. In some embodiments, the substrate is a semiconductor wafer covered by a dielectric layer made of dielectric material.

At S120, at a front face of the wafer 210, a dielectric structure is formed. By way of example, as illustrated in FIG. 2B, the dielectric structure may be formed in an upper or top portion of the wafer 210, herein referred to as structure layer 220.

In some embodiments, a first portion and a second portion that differ from one another in respect of fixed charges are formed in the wafer 210. In some implementations, the dielectric structure may be made of the same material as the wafer 210. In particular, the fixed charges can be provided by dopants in the semiconductor material of the wafer 210. In some embodiments, where the substrate has a dielectric layer of dielectric material, the fixed charges are provided by dopants in the dielectric layer of the wafer. Thus, the first portion and the second portion can differ from one another in respect of doping. In order to provide a dielectric structure layer 220, the first portion and the second portion are insulated from another. For example, shallow trench isolation can be used to electrically isolate the first portion from the second portion. In another example, a local oxidation of silicon (LOCOS) process is used to insulate the first portion from the second portion. Various embodiments illustratively provide dielectrics with incorporated fixed positive and/or negative charge carriers in an electronic component that is to be based on two-dimensional material, e.g. based on graphene, in particular on single layer graphene. As will be explained below, the electric characteristic (such as e.g. the threshold voltage of a transistor) of the electronic component is modified in a desired manner due to the electric fields generated by the dielectric charge carriers.

In some implementations, the dielectric structure is made from a different material than the wafer 210 and may e.g. be deposited over the wafer 210 (not shown). In various embodiments, the dielectric structure layer may include or be made of dielectric material such as e.g. silicon oxide (SiO₂) (e.g. undoped having a low positive charge), silicon nitride (Si3N₄), silicon carbide (SiC), aluminum aoxide (Al₂O₃), hafnium oxide (HfO₂) or zirconium oxide (ZrO₂).

Generally, in some embodiments, the method further comprises, in a first process step, doping the first portion and the second portion of the dielectric structure layer 220, and, in a second process step, only doping the second portion of the dielectric structure layer 220. As used herein, “doping” encompasses forming or otherwise providing fixed charges in the material of the dielectric structure layer 220.

In some implementations, at the front face, the wafer 210 is doped with dopants of a first conductivity type, herein also referred to as first-type dopants. It should be understood that the front face as such may not physically need to differ from a back face of the wafer 210. In some implementations, the doping is conducted selectively, i.e., as shown for example in FIG. 2B, first portions 221 of the wafer are doped while others are not. While in FIG. 2B, for simplicity, only one such doped first portion 221 is shown, the skilled person understands that more than one portion can be doped. In some implementations, the doped first portions 221 are selected in accordance with a design of one or more semiconductor devices to go into the electronic component. In FIG. 2B, a border line is indicated by a broken line 219. However, it should be understood that, the border line does not strictly need to be a line. Thus, the broken line 219 rather illustrates a region where a dopant density decreases below a threshold density. By doping the first portion 221 of the semiconductor wafer 210, in effect, a dielectric structure layer 220 is formed that has the first doped 221 portions and other portions that are not doped.

Further, the dielectric structure layer 220 can include terminal portions, for example, an emitter terminal 228 and a collector terminal 229, that are configured to be connected, electrically or otherwise, to other circuit elements (not shown).

Generally, the method thus comprises, in a first process step, doping the first portion 221 of the dielectric structure layer 220 outside the other portion, i.e., outside a second portion of the dielectric structure layer, using the first-type dopant. In some embodiments, the method further comprises, in a second process step, only doping the second portion of the dielectric structure layer 220 outside the first portion 221 of the dielectric structure layer 220 using a second-type dopant. In some embodiments, the second-type dopant differs from the first-type dopant.

Accordingly, in some implementations, at S130, the front face of the wafer 210 is doped with the second-type dopant. In particular, the doping is performed selectively, i.e., as shown, for example, in FIG. 2C, second portions 222 of the wafer 210 are doped while others are not. While in FIG. 2C, for simplicity, only one such doped second portion 222 is shown, the skilled person understands that more than one portion can be doped with the second-type dopant. In some implementations, the doped second portions 222 are selected in accordance with the design of the respective one or more semiconductor devices to go into the electronic component. In some embodiments, the first-type doped portion 221 and the second-type doped portion 222, in effect, are spaced apart by a depletion portion 224. In some embodiments, the depletion results from diffusion of first-type dopants from the first doped portion 221 into the second doped portion 222, and vice versa, i.e., from diffusion of second-type dopants from the second doped portion 222 into the first doped portion 221.

Generally, analogously to the substrate material being a semiconductor, dopants can be donor material and therefore be of a negative conductivity type. Donors are referred to as n-type dopants. The donor material can, for example, be a group V element such as, for example, phosphorus (P) or arsenic (As). For another example, the donor material is a negatively charged organic material such as polyethylene imine. Further, analogously to the substrate material being a semiconductor, dopants can be acceptor material and therefore be of a positive conductivity type. Acceptors are referred to as p-type dopants. The acceptor material can, for example, be a group III element such as aluminum (Al), boron (B) or gallium (Ga). For another example, the acceptor material can be diazonium salt. In the examples illustrated herein, the first-type dopant is an n-type dopant and the second type-dopant is a p-type dopant.

Generally, as pointed out above, dopants may be provided as fixed dielectric charge carriers within the dielectric material of the dielectric structure layer. The fixed dielectric charge carriers provided by the dopants may generate an electric field within the electronic component, e.g. to influence the electric characteristic (e.g. the electric conductivity) of a portion of the electronic component such as e.g. the portion of the electronic component through which an electric current may flow during operation of the electronic component. In some embodiments, the concentration or density of the dopants may be settable in a wide range. The dopants may be incorporated in or implanted into the dielectric material (e.g. in-situ or after the deposition of the dielectric material) e.g. by means of a vapor deposition process such as e.g. a chemical vapour deposition process (CVD), e.g. an atomic layer deposition process (ALD), or a physical vapor deposition process (PVD), an ion implantation process. The atomic layer deposition process may provide a three-dimensionally smooth deposition (coating) together an extremely good dopant concentration control. The dopants may be provided with a doping surface charge in the range from about of 10̂10 to about 10̂14/cm̂2, e.g. in the range from about of 10̂11 to about 10̂13/cm̂2.

At S140, a channel layer 230 is formed above the dielectric structure layer 220, for example, as shown in FIG. 2D. In some embodiments, the channel layer 230 comprises a two-dimensional material. In some implementations, the channel layer 230 consists of, or comprises, a two-dimensional material such as graphene, in particular a monolayer of graphene, or a metal chalcogenide such as e.g. molybdenum disulphide, tungsten disulphide, or the like. For example, the graphene layer is deposited on the dielectric structure layer 220. In particular, the graphene layer may, for example, be formed with the use of one or more of the following processes in any of the electronic components disclosed herein: Exfoliation of graphene from graphite by sonication in solvents, e.g. organic solvents a) Chemical reduction of graphene oxide (e.g. exfoliated graphene oxide); b) Chemical Vapor Deposition (CVD) of graphene; c) Formation of graphene utilizing solid phase carbon sources; d) Solid state epitaxial growth of graphene; e) Process b), c), or d), as mentioned above, in combination with a transfer process onto the desired substrate (e.g. the carrier substrate, e.g., carrier membrane). Also direct growth is possible on the dielectric substrate by CVD through a catalytic metal film and subsequent removal of the metal film.

The graphene layer may, for example, include or consist of a plurality of crystallites that may, for example, have a size (e.g. diameter) of a few micrometers, e.g. about 1 μm. In various embodiments, the graphene layer may include a continuous graphene monolayer extending over the entire substrate. Each of the crystallites may include a monolayer of graphene, herein also referred to as single layer of graphene. In one or more embodiments, the graphene monolayer may have a two-dimensional structure with a thickness of about 0.34 nm. In some implementations, the two-dimensional layer 230 may e.g. be deposited over or on the dielectric structure layer 220 by means of a transfer of the graphene layer being deposited on a catalytic metal surface or by means of a direct deposition below the catalyst layer to the dielectric material. In some implementations (not shown), an auxiliary layer is deposited on the dielectric structure layer 220 before forming the two-dimensional layer 230. The auxiliary layer can be configured to enable growth of the two-dimensional layer 230.

At S150, as shown, for example, in FIG. 2E, an insulation layer 240 is formed above the two-dimensional layer 230. In some embodiments, the method further comprises forming a dielectric insulation layer to sit between a gate layer and the two-dimensional material. For example, a dielectric substance such as silicon is deposited above the two-dimensional layer 230.

At S160, a gate layer 250 is formed. The gate layer 250 includes at least one gate. In some embodiments, the gate layer comprises one gate formed above both, the first portion of the dielectric structure layer and the second portion of the dielectric structure layer. For example, as shown in FIG. 2F, the gate can cover the first-type doped portion 221 and the second-type doped portion 222. In some embodiments, the gate can cover a depletion portion where, for example, the depletion portion 224 is formed between the first-type doped portion 221 and the second-type doped portion 222. Thus, the gate layer 250 can be configured to enable control of current flow from the first-type doped portion 221 via the two-dimensional material layer 230 to the second-type doped portion 222. In some embodiments, the gate layer comprises a first gate above the first portion of the dielectric structure layer and a second gate above the second portion of the dielectric structure layer. In some embodiments, the gate layer is configured to control current in the two-dimensional layer 230 by applying a voltage to the at least one gate.

At S199, further manufacturing processes are performed in order to obtain the electronic component.

Below, exemplary embodiments of a device manufactured, for example, according to steps of the above-described method will be described. Generally, such a device comprises a dielectric structure and a gate above the dielectric structure. The device further comprises a channel layer between the dielectric structure and the gate. In some embodiments, the device further comprises a dielectric insulation provided between the gate and the channel layer.

In some embodiments, the dielectric structure is configured to expose the channel layer to an inhomogeneous electric field. For example, in some embodiments, the inhomogeneous electric field comprises a transition from a first polarity to a second polarity. To this end, in some embodiments, the dielectric structure comprises a plurality of portions each configured to give rise to the inhomogeneous electric field. The field can differ from one portion to a neighboring portion. For example, the plurality of portions of the dielectric structure can comprise a first portion having fixed negative charges, for example a semiconductor material being doped so as to expose a corresponding first portion of the channel layer to a negative electric field. Further, the plurality of portions of the dielectric structure can comprise a second portion having fixed positive charges, for example the semiconductor material being doped so as to expose a corresponding second portion of the channel layer to a positive electric field.

In some embodiments, the plurality of portions of the dielectric structure comprises a third portion between the first portion and the second portion. In some embodiments, the third portion configured as a depletion portion. In some embodiments, the third portion, essentially, does neither have positive nor negative fixed charges, for example, the third portion is undoped semiconductor material.

In some embodiments, the channel layer comprises a two-dimensional material. In some embodiments, a band gap of the two-dimensional material is configured by exposure to the inhomogeneous electric field. In some embodiments, the channel layer comprises graphene.

In some embodiments, the device further comprises a gate configured to control current in the channel layer. In some embodiments, the gate and one portion of the dielectric structure are short-circuited. In some embodiments, the one portion of the dielectric structure that is short-circuited to the gate is p-doped.

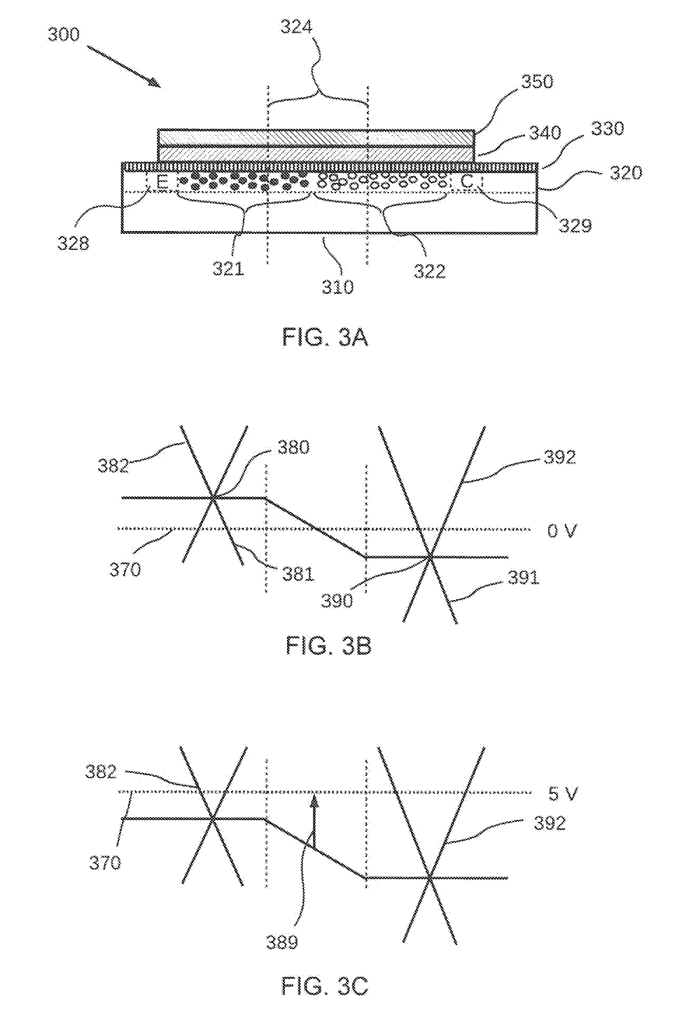

FIG. 3A shows a schematic cross-sectional view of an exemplary electronic component 300 according to some embodiments. The electronic component can be manufactured, for example, by using at least some of the steps illustrated in FIG. 1. FIGS. 3B and 3C show associated band diagrams that illustrate properties of the electronic component in some implementations.

The electronic component illustrated in FIG. 3A is essentially as described above with respect to FIGS. 2A to 2F. Accordingly, the electronic component comprises a substrate 310, a dielectric structure layer 320, a two-dimensional layer 330, an insulation layer 340 and a gate layer 350. Details regarding, for example, the materials used to compose the electronic component can be as described above to FIGS. 2A to 2F and are not all described again.

The dielectric structure layer 320 comprises an emitter terminal portion 328 and a collector terminal portion 329. Between the emitter terminal portion 328 and the collector terminal portion 329 are a provided first-type doped portion 321 and, adjacent to the first-type doped portion 321, a second-type doped portion 322. In some examples, the first-type dopant is an n-type dopant, while the second-type dopant is a p-type dopant. In a junction portion 324, the first-type doped portion 321 and the second-type doped portion 322 abut. Thus, in the junction portion 324, a pn-junction is formed that is essentially depleted of charge carriers. Therefore, the junction portion 324 may also be referred to as depletion portion or depletion region.

In addition to the cross-sectional schematic view of the exemplary electronic component, FIGS. 3B and 3C, on the left-hand side bottom, show a lower Dirac cone 381, a Dirac point 380 and an upper Dirac cone 382 of material such as graphene in the two-dimensional layer 330 where exposed to the first-type doped portion 321 of the semiconductor structure layer 320. Further, FIGS. 3B and 3C, on the right-hand side bottom, show a lower Dirac cone 391, a Dirac point 390 and an upper Dirac cone 392 of material in the two-dimensional layer 330 where exposed to the second-type doped portion 322 of the semiconductor structure layer 320.

Still further, FIGS. 3B and 3C show a level 370 of the Fermi energy of material in the two-dimensional layer 330. As the material's Fermi energy level is the highest level of energy that an electron of that material can have in the material's base state, or non-excited state, up to the level of the Fermi energy, all energy levels are fully occupied by electrons, while above the level of the Fermi energy, there are no electrons. Thus, the level of the Fermi energy, for example, in graphene that is not doped, is exactly at the intersection of the Dirac cones. In contrast, doping the semiconductor substrate in the dielectric structure layer 220 introduces allowed energy states within the band gap of the semiconductor and can indirectly dope the material of the two-dimensional layer 320 as will now be explained.

The energy states of the semiconductor substrate material are close to the energy band that corresponds to the dopant type. In the case of n-type dopants, electron donor impurities create states near the conduction band, while, in the case of p-type dopants, electron acceptor impurities create states near the valence band. At least one effect of the dopants in the semiconductor substrate material can be that an energy band is shifted relative to the semiconductor's Fermi energy. In other words, for example, doping of a group IV semiconductor with a group V element shifts the level of the Fermi energy of the semiconductor in the direction of the conduction band. In contrast, doping of a group IV semiconductor with a group III element shifts the level of the Fermi energy of the semiconductor in the direction of the valence band.

Further, one effect of the doped dielectric structure layer 320 can be that electrical properties of the two-dimensional material of the two-dimensional layer 330 are affected; herein, this effect is also referred to as ‘indirect doping’ of the two-dimensional layer 330. In particular, the Dirac point, i.e., the point where the valence band and the conduction band of the two-dimensional material contact each other, can be shifted relative to two-dimensional layer material that is not exposed to any doped dielectric material.

In some implementations, in the first-type doped portion 321 the substrate material of the dielectric structure layer 320 is n-type doped, i.e., an electron density in the substrate material of the dielectric structure layer 320 is increased. In the two-dimensional layer 330, for example in the graphene monolayer, where exposed to the negative electric field of the substrate material in the first-type doped portion 321, negative mobile charge carriers, i.e., electrons, are pushed away. In other words, positive charge carriers, i.e., holes, are induced into the two-dimensional layer 330. Accordingly, the n-type doped portion 321 of the substrate material of the dielectric structure layer 320 causes indirect doping of the two-dimensional layer 330 to be p-type doping. Accordingly, relative to the Dirac point of un-doped two-dimensional material, the Dirac point 380 of the two-dimensional layer material is positively shifted as shown, for example, in the band diagram of FIG. 3B, left-hand side. At least one effect is that the level 370 of Fermi energy is in the lower Dirac cone 381 as indicated in FIG. 3B. Correspondingly, for example, in the second doped portion 322 the substrate material is p-type doped. The p-type doped substrate material of the dielectric structure layer 320 causes indirect doping of the two-dimensional layer 330 to be n-type doping, where a surplus of electrons is present in the two-dimensional material. In other words, negative charge carriers, i.e., electrons, are accumulated in the two-dimensional layer 330. Accordingly, the p-type doped portion 322 of the substrate material of the dielectric structure layer 320 causes indirect doping of the two-dimensional layer 330 to be n-type doping. Accordingly, relative to the Dirac point of un-doped two-dimensional material, the Dirac point 390 of the two-dimensional layer material is negatively shifted as shown, for example, in the band diagram of FIG. 3B, right-hand side. At least one effect is that the level 370 of Fermi energy is in the upper Dirac cone 392 as indicated in FIG. 3B.

Thus, in the example illustrated in FIG. 3A, the electronic component is provided as a diode. Because mobile charge carriers of the n-type doped semiconductor move to fill holes of the p-type doped semiconductor, whereby the conduction bands of both, n-type doped semiconductor and p-type doped semiconductor end up essentially depleted from mobile charge carriers, current cannot flow in the depletion region 324 between the emitter terminal 328 and the source terminal 329.

Now, a positive voltage is applied to the gate of the gate layer 350. In the electric field between the gate layer 350 and dielectric structure layer 320, mobile negative charge carriers are pulled towards the gate. Thereby, where the two-dimensional layer 330 material is positively doped, as in the example discussed above where the first-type portion 321 of the dielectric structure layer 320 is n-type doped, the negative charge carriers of the substrate fill holes in the two-dimensional layer 330 and, if the voltage at the gate is sufficiently strong, provide a surplus of negative charge carriers. Where the two-dimensional layer material is indirectly negatively doped, as in the example discussed above where the second-type portion 322 of the dielectric structure layer 320 is p-type doped, negative charge carriers of the substrate are attracted to the indirectly n-type doped two-dimensional layer 330 where even more negative charge carriers will accumulate. Provided the gate voltage is sufficiently positive, irrespective of the fixed charges of the dielectric structure layer 320, the level 370 of the Fermi energy is above the valence band and in the upper Dirac cone 382, 392. Thus, an effect can be that the pn-junction of the electronic component becomes an nn-junction. In other words, by applying the voltage to the gate, the electronic component can be controlled to be either blocking (no voltage or insufficient voltage at the gate), or negatively conductive (sufficient positive voltage at the gate) or positively conductive (sufficient negative voltage at the gate). At least one effect can be that the pn-diode according to the above-disclosed embodiments can be switched or configured to be normally on or off by applying a suitable gate voltage to the diode.

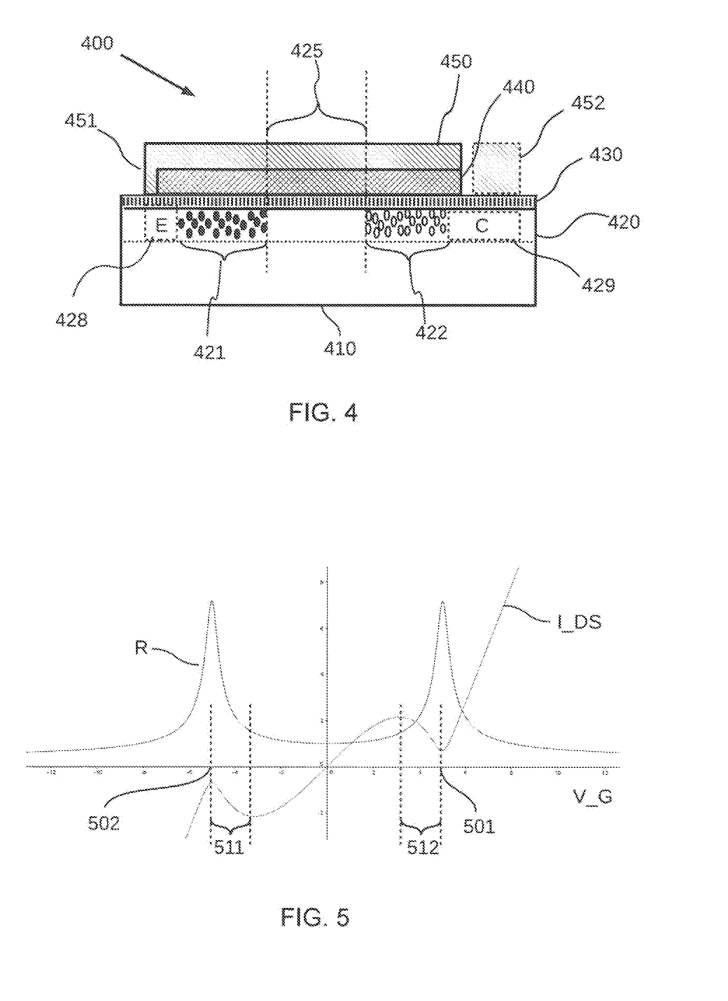

FIG. 4 is a schematic cross-sectional view that illustrates an electronic component 400 according to some embodiments. The electronic component 400 illustrated in FIG. 4 is essentially as described above with respect to FIGS. 2A to 2F, and FIG. 3A. Accordingly, the electronic component 400 comprises a substrate 410, a dielectric structure layer 420, a two-dimensional layer 430, an insulation layer 440 and a gate layer 450. Details regarding, for example, the materials used to compose the electronic component 400 can be as described above to FIGS. 2A to 2F and are not all described again.

In some embodiments, the gate layer 450 is coupled to one portion of the dielectric structure layer 420. For example, as illustrated in FIG. 4, a gate in the gate layer 450 is formed, for example by a gate via 451 that penetrates the insulation layer 440, so as to couple to an emitter via 428 in contact with the first-type doped portion 421 in the dielectric structure layer 420, i.e., with an n-type doped charge reservoir. Thus, the emitter terminal 458 forms a cathode. Likewise, a collector terminal 452 can be formed in the insulation layer 440 so as to couple to a collector terminal 429 in the dielectric structure layer 420 that is in contact with the second-type doped portion 422, i.e., with an n-type doped charge reservoir such that the collector terminal 452 can act as an anode. In some embodiments, a good conductor such as gold (Au) is used as a material of the gate. As described above, for example, with reference to FIG. 3A, material of the two-dimensional layer 430 is subject to indirect doping caused by the dopants of the first-type doped portion 421 and by the dopants of the second-type doped portion 422.

Unlike the examples discussed above, in embodiments as shown in FIG. 4, the first-type doped portion 421 and the second-type doped portion 422 do not abut but are sufficiently separated from one another by an undoped portion 425 to essentially avoid formation of any depletion region between the first-type doped portion 421 and the second-type doped portion 422. At least one effect can be that a resistance R of the two-dimensional layer 430 between the emitter terminal 428 and the collector terminal 429 is essentially a sum of a first resistance that is provided by indirectly doped material above the first-type doped portion 421 and a second resistance that is provided by indirectly doped material above the second-type doped portion 422.

FIG. 5 shows a diagram that illustrates a resistance R of the electronic component 400. Further, the diagram illustrates an exemplary characteristic plot of drain source current I_DS versus voltage V_G applied at the gate of the electronic component. While in the description that follows, reference will be made to the voltage V_G as gate voltage, it should be understood that, since the gate layer 450 of the electronic component 400 is short circuited to the emitter terminal 428, the gate voltage V_G is, in effect an operational voltage that equals the voltage between emitter and collector or, in other words, or the voltage V_DS between source and drain of the electronic component 400.

The resistance R of the material of the two-dimensional layer 430 has a first contribution from the material facing the first-type doped portion 421 and being indirectly doped thereby. Further, the resistance R of the material of the two-dimensional layer 430 has a second contribution from the material facing the second-type doped portion 422 and being indirectly doped thereby.

The resistance R depends on the gate voltage V_G. In the exemplary embodiment that is illustrated in FIG. 5, the resistance R is symmetric for positive and negative values of the gate voltage V_G. It should be understood that the symmetry reflects a structure of the dielectric structure layer 420 where the first-type doped portion 421 and the second-type portion 422 are essentially equally charged with dopants, albeit with opposite polarity. In another implementation (not shown), an amount, charge and charge density of dopants in the dielectric structure layer can be selected so as to achieve a desired characteristic behavior of the electronic component wherein, in particular, a dependency of the resistance of the two-dimensional layer from the gate voltage V_G is asymmetric with respect to the gate voltage V_G=o.

In the example, the resistance R peaks at a gate voltage, for example, V_G=−5 V and at a gate voltage, for example, V_G=+5 V. It should be understood that the peak of the resistance at the positive gate voltage V_G is due to the indirect doping of the material in the two-dimensional layer 430 above the first-type doped portion 421 of the dielectric structure layer 420.

As described above, in the example, the first-type dopants are n-type dopants that provide an excess of negative charge carriers and thereby indirectly p-type dope the material of the two-dimensional layer 430. A positive gate voltage, V_G>o, attracts negative charge carriers of the n-type doped portion in the dielectric structure layer 420. Thus, the positive gate voltage V_G reduces the number of positive charge carriers in the material of the two-dimensional layer 430. The resistance of the material in the two-dimensional layer 430 peaks at a gate voltage 501 that compensates the effect of indirect doping of the material in the two-dimensional 430 by the n-type doped portion 421 of the dielectric structure layer 420.

Likewise, in the example, the second-type dopants are p-type dopants that provide a lack of negative charge carriers, i.e., an excess of holes as positive charge carriers, and thereby indirectly n-type dope the material of the two-dimensional layer 430. A negative gate voltage V_G<o repels negative charge carriers from the material in the two-dimensional layer 430 into the n-type doped portion in the dielectric structure layer 420. Thus, the negative gate voltage V_G reduces the number of negative charge carriers in the material of the two-dimensional layer 430. The resistance of the material in the two-dimensional layer 430 peaks at a gate voltage 502 that compensates the effect of indirect doping of the material in the two-dimensional layer 430 by the p-type doped portion 422 of the dielectric structure layer 420.

Using the gate voltage V_G, the electronic component 400 can be tuned, wherein the tuning can be calculated using the formula for the resistance R as a function of the gate voltage V_G:

R=R_C+L/W*1/μ_FE*1√(e² no²+C_ox²[V_G−V_Dirac]²)

wherein R_C is a contact resistance between the gate layer 450 and the two-dimensional layer 430, L is a length of the graphene channel, W is a width of the graphene channel, μ_FE is the field effective mobility, e is the electron charge, no is the density of electrons in the graphene, C_ox is the electrostatic capacitance of the structure provided by the gate layer 450, insulation layer 440 and the two-dimensional layer 430, and V_Dirac is the voltage level of the Dirac point. Thus, a method of operation of the NDR diode can comprise calculation of a voltage to be set at the gate V_G in order to achieve a desired resistance.

Accordingly, the current I_DS through the device as a function of the voltage V_G at the gate is:

I_DS(V_G)=V_G/R

As shown in FIG. 5, the electronic component 400 has the characteristic of a negative differential resistance (NDR) diode. Generally, a current-voltage (IV) characteristic of the electronic component is such that the larger the source-drain voltage is, the smaller is the current I_DS. However, for some values of the gate voltages V_G, this behavior is reversed, i.e., the larger the gate voltage V_G is, the smaller is the current I_DS. Beginning with negative values, a first such voltage range 511 starts with the negative value 502 of the gate voltage V_G that compensates the effect of indirect doping of the material in the two-dimensional layer 430 by the p-type doped portion 422 of the dielectric structure layer 420. A second such voltage range 512 ends with the positive value 501 of the gate voltage V_G that compensates the effect of indirect doping of the material in the two-dimensional layer 430 by the n-type doped portion 421 of the dielectric structure layer 420.

Further, in the example, where no gate voltage V_G is applied, the current I_DS is blocked. As pointed out above when discussing the resistance R, it should be understood that the structure of the dielectric structure layer, in particular, in respect of doping, can be designed to provide the electronic component with a different IV-characteristic. In particular, a blockage of current need not occur if the gate voltage V_G=o, but can occur at a non-zero value of the gate voltage V_G.

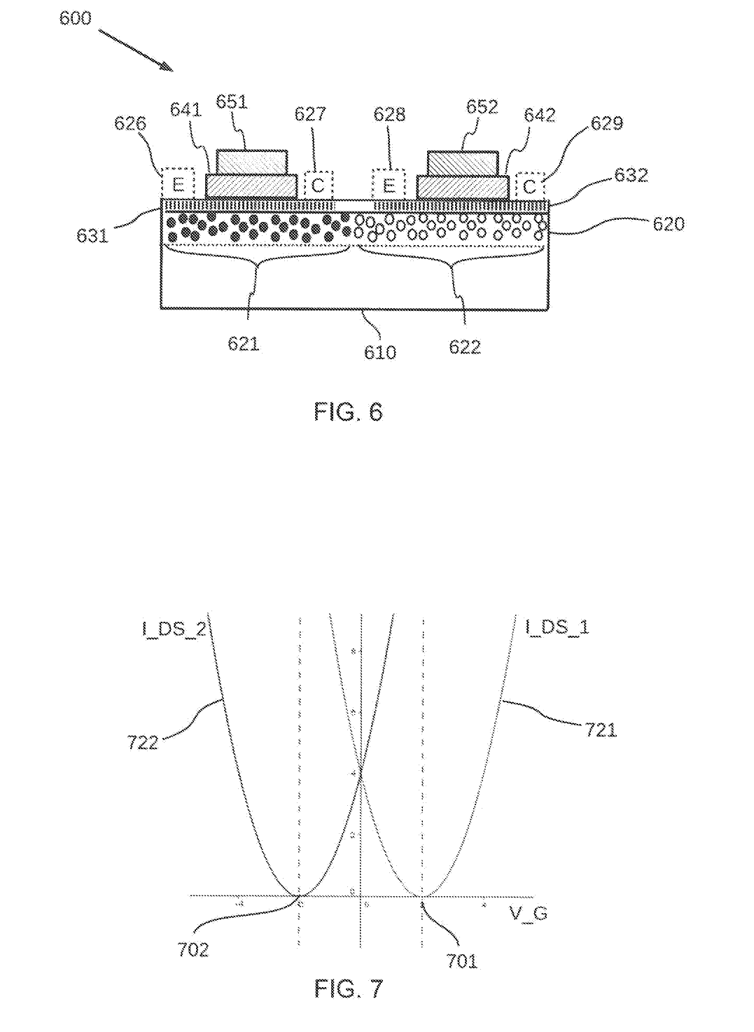

FIG. 6 is a schematic cross-sectional view that illustrates an electronic component 600 according to some embodiments.

The electronic component 600 illustrated in FIG. 6 is essentially as described above with respect to FIGS. 2A to 2F, and FIG. 3A. Accordingly, the electronic component 600 comprises a substrate 610, a dielectric structure layer 620 that comprises a first-type doped portion 621 and a second-type doped portion 622, a two-dimensional layer, an insulation layer and a gate layer. Details regarding, for example, the materials used to compose the electronic component 600 can be as described above to FIGS. 2A to 2F and are not all described again.

In some embodiments, the gate layer comprises a plurality of gates each configured to control current in the channel layer. At least two gates of the plurality of gates form part of a pair of complementary transistors. For example, in some embodiments, as illustrated in FIG. 6, the electronic component 600 comprises a pair of complementary transistors.

A first transistor is provided above the first-type doped portion 621. In the two-dimensional layer, a first sheath 631 of two-dimensional material, such as monolayer graphene, is provided above the first-type doped portion 621 to provide for a channel of the first transistor. A first emitter terminal 626 and a first collector terminal 627 are formed on the first sheath 631. In an alternate embodiment (not shown), the first emitter terminal and the first collector terminal can be formed below the first sheath. The first emitter terminal 626 and the first collector terminal 627 are spaced apart from one another by insulating material 641. Above the insulating material 641, a first gate 651 is formed.

A second transistor is formed above the second-type doped portion 622. In the two-dimensional layer, a second sheath 632 of two-dimensional material is provided above the second-type doped portion 622 to provide for a channel of the second transistor. A second emitter terminal 628 and a second collector terminal 629 are formed on the second sheath 632. The second emitter terminal 628 and the second collector terminal 629 are spaced apart from one another by insulating material 642. Above the insulating material 642, a second gate 652 is formed.

As described above with reference to other embodiments, the first-type doped portion 621 of the dielectric structure layer 620 indirectly dopes the two-dimensional material of the first sheath 631. Depending on a type of dopants used, the Dirac point of the two-dimensional material can be shifted to negative or to positive voltages. For example, where the first-type doped portion of the dielectric structure layer 620 is formed by n-type dopants, the two-dimensional material's Dirac point is positively shifted, since the first sheath 631, due to its exposure of the n-type doped portion of the dielectric structure layer 62o, is indirectly p-type doped. In contrast, where the first-type doped portion is formed by p-type dopants, the two-dimensional material's Dirac point is negatively shifted, since the first sheath 631, due to its exposure of the p-type doped portion of the dielectric structure layer 62o, is indirectly n-type doped.

Likewise, the second-type doped portion 622 of the dielectric structure layer 620 indirectly dopes the two-dimensional material of the second sheath 632.

FIG. 7 shows a diagram that illustrates an exemplary characteristic behavior of the electronic component 600 described above with reference to FIG. 6.

In particular, a first curve 721 illustrates a first current I_DS_1 of the first transistor where the first-type doped portion 621 is formed using n-type dopants in the dielectric structure layer 620. As described above, in such a case the Dirac point of the two-dimensional material is positively shifted. Accordingly, a positive gate voltage V_G reduces the number of positive charge carriers in the material of the two-dimensional layer 630. At a blocking gate voltage 704 indirect doping of the material in the two-dimensional layer 630 by the n-type doped portion 621 of the dielectric structure layer 620 is compensated and no current I_DS_1 flows.

Further, a second curve 722 illustrates a second current I_DS_2 of the second transistor where the second-type doped portion 622 is formed using p-type dopants in the dielectric structure layer 620. As described above, in such a case the Dirac point of the two-dimensional material is negatively shifted. Accordingly, a negative gate voltage V_G reduces the number of negative charge carriers in the material of the two-dimensional layer 630. At a blocking gate voltage 702, indirect doping of the material in the two-dimensional layer 630 by the p-type doped portion 622 of the dielectric structure layer 620 is compensated and no current I_DS_2 flows.

In the above description of exemplary implementations, for purposes of explanation, specific numbers, materials configurations, and other details are set forth in order to better explain the invention, as claimed. However, it will be apparent to one skilled in the art that the claimed invention may be practiced using different details than the exemplary ones described herein. It is further to be understood that the features of the various embodiments described herein may be combined with each other, unless specifically noted otherwise.

In one aspect, a method for use in manufacturing an electronic component comprises forming a layered structure comprising a dielectric structure layer, a channel layer and a gate layer. The dielectric structure layer is formed so as to comprise a first portion and a second portion that differ from one another in respect of fixed charges. The channel layer comprises a two-dimensional material, and the gate layer comprises a gate formed above both, the first portion of the dielectric structure layer and the second portion of the dielectric structure layer. In some implementations, the method further comprises forming a dielectric insulation layer to sit between the gate layer and the two-dimensional material.

In some implementations, in order to form the dielectric substrate layer, the method comprises, in a first process step, doping the first portion and the second portion of a substrate of a semiconductor substrate. In a second process step, only the second portion is doped. In some implementations, the method further comprises, in a first process step, doping the first portion of the semiconductor substrate outside the second portion using a first-type dopant and, in a second process step, only doping the second portion of the wafer outside the first portion using a second-type dopant. In some implementations, doping in the first process step uses a first-type dopant and doping in the second process step uses a second-type dopant that differs from the first-type dopant. In some implementations, the first-type dopant is an n-type dopant and the second type-dopant is a p-type dopant.

In some implementations, the two-dimensional material comprises graphene. In some implementations, the channel layer comprises monolayer graphene.

In some implementations, the method further comprises providing a conductive connection between the gate and one of the first portion of the dielectric structure layer and the second portion of the dielectric structure layer.

In another aspect, a device for use as an electronic component comprises a dielectric structure and a gate above the dielectric structure. The device further comprises a two-dimensional material between the dielectric structure and the gate. The dielectric structure is configured to expose the two-dimensional material to an inhomogeneous electric field. In some embodiments, a band gap of the two-dimensional material is configured by exposure to the inhomogeneous electric field. In some embodiments, the inhomogeneous electric field comprises a transition from a first polarity to a second polarity.

In some embodiments, the dielectric structure comprises a plurality of portions each configured to give rise to the inhomogeneous electric field differing from one portion to a neighboring portion. In some embodiments, the plurality of portions of the dielectric structure comprise a first portion being doped so as to expose a corresponding first portion of the channel layer to a negative electric field and a second portion being doped so as to expose a corresponding second portion of the channel layer to a positive electric field. In some embodiments, the plurality of portions of the dielectric structure comprises a third portion between the first portion and the second portion, wherein the third portion is electrically insulating the first portion from the second portion. In some embodiments, the third portion is undoped.

In some embodiments, the channel layer comprises a two-dimensional material. In some embodiments, the channel layer comprises graphene. Some embodiments comprise a gate that is configured to control current in the channel layer. Some embodiments further comprise a dielectric insulation provided between the gate and the channel layer. In some embodiments, the gate and one portion of the dielectric structure are short-circuited. In some embodiments, the one portion of the dielectric structure that is short-circuited to the gate is p-doped.

In some embodiments, the device further comprises a semiconductor base substrate that supports the dielectric structure.

In one aspect, a method for use in manufacturing an electronic component comprises providing a semiconductor substrate and forming a layered structure comprising a dielectric structure layer, a channel layer and a gate layer. The dielectric structure layer comprises a first portion and a second portion that differ from one another in respect of fixed charges. The channel layer comprises a two-dimensional material. The gate layer comprises a first gate above the first portion of the dielectric structure layer and a second gate above the second portion of the dielectric structure layer. In some implementations the method further comprises forming a dielectric insulation layer to sit between the gate layer and the two-dimensional material.

The method further comprises, in a first process step, doping a first portion and a second portion of the semiconductor substrate. In a second process step, only the second portion of the semiconductor substrate is doped.

In some implementations, the method further comprises forming the dielectric structure layer by providing a non-conductive barrier between the first portion and the second portion of the semiconductor substrate.

In some implementations the method further comprises, in a first process step, doping the first portion of the semiconductor substrate outside the second portion of the semiconductor substrate using a first-type dopant. In a second process step, only the second portion of the semiconductor substrate outside the first portion of the semiconductor substrate is doped using a second-type dopant.

The method further comprises forming the dielectric structure layer by providing a non-conductive barrier between the first portion and the second portion of the semiconductor substrate.

In some implementations, doping in the first process step uses a first-type dopant and doping in the second process step uses a second-type dopant that differs from the first-type dopant. In some implementations, the first-type dopant is a n-type dopant and the second type-dopant is an p-type dopant.

In some implementations, the gate layer comprises a first gate formed above the first portion of the dielectric structure layer and a second gate above the second portion of the dielectric structure layer. In some implementations, the gate layer comprises a gate formed above both, the first portion of the dielectric structure layer and the second portion of the dielectric structure layer.

In some implementations, the method further comprises providing a conductive connection between the gate and one of the first portion of the dielectric structure layer and the second portion of the dielectric structure layer.

In one aspect a device for use as an electronic component comprises a dielectric structure and a gate layer and a two-dimensional material between the dielectric structure and the gate layer. In some embodiments, the dielectric structure is configured to expose the two-dimensional material to an inhomogeneous electric field, and In some embodiments, the gate layer comprises a plurality of gates each configured to control current in the channel layer.

In some embodiments, a band gap of the two-dimensional material is configured by exposure to the inhomogeneous electric field. In some embodiments, the inhomogeneous electric field comprises a transition from a first polarity to a second polarity. In some embodiments, the dielectric structure comprises a plurality of portions each configured to give rise to the inhomogeneous electric field differing from one portion to a neighboring portion.

In some embodiments, the plurality of portions of the dielectric structure comprises a first portion being doped so as to expose a corresponding first portion of the channel layer to a negative electric field and a second portion being doped so as to expose a corresponding second portion of the channel layer to a positive electric field. In some embodiments, the plurality of portions of the dielectric structure comprises a third portion between the first portion and the second portion. In some embodiments, the third portion is insulating. In some embodiments, the third portion is configured as a depletion portion. In some embodiments, the third portion is undoped.

In some embodiments, the channel layer comprises a two-dimensional material. In some embodiments, the channel layer comprises graphene.

In some embodiments, the plurality of gates comprises at least two gates that form part of a pair of complementary transistors. In some embodiments, the device further comprises a dielectric insulation provided between the gate and the channel layer.

In some embodiments, the device further comprises a semiconductor base substrate that supports the dielectric structure.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. It is intended that this invention be limited only by the claims and the equivalents thereof.

The word “exemplary” is used herein to mean “serving as an example, instance, or illustration”. Any embodiment or design described herein as “exemplary” is not necessarily to be construed as preferred or advantageous over other embodiments or designs.

As used herein, the terms ‘at least one’ and ‘one or more’ may be understood to include any integer number equal to one or greater than one, i.e. one, two, three, four, etc.

The term ‘a plurality’ may be understood to include any integer number greater than or equal to two, i.e. two, three, four, five, etc.

The word ‘over’, used herein to describe forming a feature, e.g. a layer ‘over’ a side or surface, may be used to mean that the feature, e.g. the layer, may be formed ‘directly on’, e.g. in direct contact with, the implied side or surface. The word ‘above’, used herein to describe forming a feature, e.g. a layer ‘above’ a side or surface, may be used to mean that the feature, e.g. the layer, may be formed ‘indirectly on’ the implied side or surface with one or more additional layers being arranged between the implied side or surface and the formed layer.

The term ‘coupling’ or ‘connection’ may include both an indirect “coupling” or “connection” and a direct “coupling” or “connection”.

As used herein, the word ‘exemplary’ means serving as an example, instance, or illustration. Any aspect or design described herein as ‘exemplary’ is not necessarily to be construed as preferred or advantageous over other aspects or designs. Rather, use of the word exemplary is intended to present concepts and techniques in a concrete fashion. The term ‘techniques,’ for instance, may refer to one or more devices, apparatuses, systems, methods, articles of manufacture, and/or computer-readable instructions as indicated by the context described herein.

As used herein, the term ‘or’ is intended to mean an inclusive ‘or’ rather than an exclusive ‘or.’ That is, unless specified otherwise or clear from context, ‘X employs A or B’ is intended to mean any of the natural inclusive permutations. That is, if X employs A; X employs B; or X employs both A and B, then ‘X employs A or B’ is satisfied under any of the foregoing instances.

As used herein, the articles ‘a’ and ‘an’ should generally be construed to mean ‘one or more,’ unless specified otherwise or clear from context to be directed to a singular form.

As used herein, the terms ‘having’, ‘containing’, ‘including’, ‘with’ or variants thereof, and like terms are open ended terms intended to be inclusive. These terms indicate the presence of stated elements or features, but do not preclude additional elements or features.

As used herein, directional terminology, such as ‘top’, ‘bottom’, ‘front’, ‘back’, ‘leading’, ‘trailing’, etc., is used with reference to the orientation of the figure(s) being described.

As used herein, terms such as ‘first’, ‘second’, and the like, are also used to describe various elements, regions, sections, etc. and are also not intended to be limiting.

What is claimed is:

1. A method, for use in manufacturing an electronic component, the method comprising:
forming a layered structure comprising a dielectric structure layer, a channel layer and a gate layer,
wherein the dielectric structure layer comprises a first portion and a second portion that differ from one another in respect of fixed charges,
wherein the channel layer comprises a two-dimensional material, and
wherein the gate layer comprises a gate formed above both the first portion of the dielectric structure layer and the second portion of the dielectric structure layer.

2. The method of claim 1, the method further comprising:
forming a dielectric insulation layer to sit between the gate layer and the two-dimensional material.

3. The method of claim 1, the method further comprising:
in a first process step, doping the first portion and the second portion of the dielectric structure layer, and
in a second process step, only doping the second portion of the dielectric structure layer.

4. The method of claim 1, the method further comprising:
in a first process step, doping the first portion of the dielectric structure layer outside the second portion of the dielectric structure layer using a first-type dopant, and
in a second process step, only doping the second portion of the dielectric structure layer outside the first portion of the dielectric structure layer using a second-type dopant.

5. The method of claim 3,
wherein doping in the first process step uses a first-type dopant, and
wherein doping in the second process step uses a second-type dopant that differs from the first-type dopant.

6. The method of claim 5, wherein the first-type dopant is an n-type dopant and the second-type dopant is a p-type dopant.

7. The method of claim 1, wherein the two-dimensional material comprises graphene.

8. The method of claim 1, wherein the channel layer comprises monolayer graphene.

9. The method of claim 8, the method further comprising:
providing a conductive connection between the gate and one of the first portion of the dielectric structure layer and the second portion of the dielectric structure layer.

10. A device for use as an electronic component, the device comprising:
a dielectric structure and a gate above the dielectric structure; and
a two-dimensional material between the dielectric structure and the gate,
wherein the dielectric structure is configured to expose the two-dimensional material to an inhomogeneous electric field.

11. The device of claim 10, wherein a band gap of the two-dimensional material is configured by exposure to the inhomogeneous electric field.

12. The device of claim 10, wherein the inhomogeneous electric field comprises a transition from a first polarity to a second polarity.

13. The device of claim 10, wherein the dielectric structure comprises a plurality of portions each configured to give rise to the inhomogeneous electric field differing from one portion to a neighboring portion.

14. The device of claim 13,
wherein the plurality of portions of the dielectric structure comprises a first portion being doped so as to expose a corresponding first portion of the two-dimensional material to a negative electric field, and
wherein the plurality of portions of the dielectric structure comprises a second portion being doped so as to expose a corresponding second portion of the two-dimensional material to a positive electric field.

15. The device of claim 14, wherein the plurality of portions of the dielectric structure comprises a third portion between the first portion and the second portion, wherein the third portion is undoped.

16. A device comprising:
a dielectric structure; and
a channel layer disposed above the dielectric structure,
wherein the dielectric structure is configured to expose the channel layer to an inhomogeneous electric field.

17. The device of claim 16, wherein the channel layer comprises a two-dimensional material.

18. The device of claim 17, wherein the channel layer comprises graphene.

19. The device of claim 16, the device further comprising a gate configured to control current in the channel layer.

20. The device of claim 19, the device further comprising a dielectric insulation provided between the gate and the channel layer.

21. The device of claim 20, wherein the gate and one portion of the dielectric structure are short-circuited.

22. The device of claim 21, wherein the one portion of the dielectric structure that is short-circuited to the gate is p-doped.

23. The device of claim 16, further comprising a semiconductor base substrate that supports the dielectric structure.
